(19) United States
(12) Patent Application Publication
(10) Pub. No.: US 2026/0231612 A1
(43) Pub. Date: Aug. 6, 2026

(54) ELECTRONIC DEVICE

(71) Applicant: Samsung Display Co., LTD., Yongin-si (KR)

(72) Inventor: MINJUN JANG, Yongin-si (KR)

(21) Appl. No.: 19/350,025

(22) Filed: Oct. 5, 2025

(30) Foreign Application Priority Data
Feb. 4, 2025 (KR) 10-2025-0013471

(51) Int. Cl. H10K 59/121; H10K 59/122; H10K 59/131

(52) U.S. Cl. CPC H10K 59/1213; H10K 59/122; H10K 59/131

(57) ABSTRACT

Provided is an electronic device including a substrate including a light-emitting part, and a plurality of transmissive parts adjacent to the light-emitting part, and a pixel unit disposed on the light-emitting part. The pixel unit may include a first portion including a plurality of first light-emitting elements which are arranged in a first direction, a second portion symmetrical with the first portion with respect to an axis parallel to the first direction, and including a plurality of second light-emitting elements which are arranged in the first direction, a bus electrode disposed between the first portion and the second portion when viewed on a plane, and a pixel-defining film covering a border of the bus electrode and exposing a portion of the bus electrode.

This application claims priority to Korean Patent Application No. 10-2025-0013471, filed on Feb. 4, 2025, and all the benefits accruing therefrom under 35 U.S.C. § 119, the content of which in its entirety is herein incorporated by reference.

### BACKGROUND

### Field

The present disclosure herein relates to an electronic device.

### Description of the Related Art

Electronic apparatuses, such as a smart phone, a digital camera, a laptop computer, a navigation unit, and a smart television, for providing an image to a user include an electronic device for displaying the image. The electronic device generates an image and provides the image to the user via a display screen.

Recently, with the technological development for the electronic device, various types of electronic devices such as a transparent electronic device are being developed. A transparent electronic device may include a transparent display panel. The transparent display panel may include a plurality of pixels and a plurality of transmissive parts. Images may be displayed by the pixels, and light may be transmitted through the transmissive parts. The light transmittances of the transmissive parts may be higher than the light transmittances of the pixels. The transmissive parts may allow objects disposed on a rear surface of the electronic device to be viewed by a user.

### SUMMARY

The present disclosure provides an electronic device which includes transmissive parts with increased areas.

An embodiment of the inventive concept provides an electronic device including: a substrate including a light-emitting part and a plurality of transmissive parts adjacent to the light-emitting part; and a pixel unit disposed on the light-emitting part, wherein the pixel unit includes a first portion including a plurality of first light-emitting elements which are arranged in a first direction, a second portion symmetrical with the first portion with respect to an axis parallel to the first direction, and including a plurality of second light-emitting elements which are arranged in the first direction, a bus electrode disposed between the first portion and the second portion when viewed on a plane, and a pixel-defining film covering a border of the bus electrode and exposing a portion of the bus electrode.

In an embodiment of the inventive concept, an electronic device includes: a substrate including a light-emitting part, and a plurality of transmissive parts adjacent to the light-emitting part; and a pixel unit disposed on the light-emitting part. The pixel unit includes: a first portion including a plurality of first pixel transistors which are disposed on the substrate and a plurality of first light-emitting elements which are disposed on the plurality of first pixel transistors and electrically connected to the plurality of first pixel transistors, a second portion including a plurality of second pixel transistors which are disposed on the substrate and a plurality of second light-emitting elements which are disposed on the plurality of second pixel transistors and electrically connected to the plurality of second pixel transistors, a (1-1)-th power line disposed between the plurality of first pixel transistors and the plurality of first light-emitting elements, electrically connected to the plurality of first light-emitting elements, and which applies a first voltage, a (1-2)-th power line disposed between the plurality of second pixel transistors and the plurality of second light-emitting elements, electrically connected to the plurality of second light-emitting elements, and which applies the first voltage; and a second power line disposed between the first portion and the second portion when viewed on a plane, electrically connected to the plurality of first light-emitting elements and the plurality of second light-emitting elements, and which applies a second voltage having a lower level than the first voltage.

In an embodiment of the inventive concept, an electronic device includes: a power module; and a display module electrically connected to the power module, wherein the display module includes a substrate including a light-emitting part, and a plurality of transmissive parts which are adjacent to the light-emitting part, and a pixel unit disposed on the light-emitting part, the pixel unit includes a first portion including a plurality of first light-emitting elements which are arranged in a first direction, a second portion symmetrical with the first portion with respect to an axis parallel to the first direction, and including a plurality of second light-emitting elements which are arranged in the first direction, a bus electrode disposed between the first portion and the second portion when viewed on a plane, and a pixel-defining film covering a border of the bus electrode and exposing a portion of the bus electrode.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an electronic device according to an embodiment of the inventive concept;

FIG. 2 is a schematic view of each of electronic devices according to various embodiments;

FIG. 3 is a perspective view of an electronic device according to an embodiment of the inventive concept;

FIG. 4 is a schematic cross-sectional view of a display module;

FIG. 5 exemplarily illustrates a cross-sectional view of a display panel illustrated in FIG. 4;

FIG. 6 is a block diagram of the display module illustrated in FIG. 4;

FIG. 7 is a view illustrating an equivalent circuit of a first pixel, a second pixel, and a third pixel of included among pixels illustrated in FIG. 6;

FIG. 8 is an equivalent circuit diagram of the first pixel illustrated in FIG. 7;

FIG. 9 is an enlarged plan view of a first region AA1 illustrated in FIG. 6;

FIG. 10 is a cross-sectional view of a display part taken along line I-I′ illustrated in FIG. 9;

FIGS. 11A to 11H are plan views sequentially illustrating a planar structure of some of the pixels illustrated in FIG. 9; and

FIG. 12 is a plan view of a light-emitting part according to an embodiment of the inventive concept.

### DETAILED DESCRIPTION

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, and the like may be used herein to describe various elements, the elements are not to be limited by these terms. These terms are used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

In some aspects, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

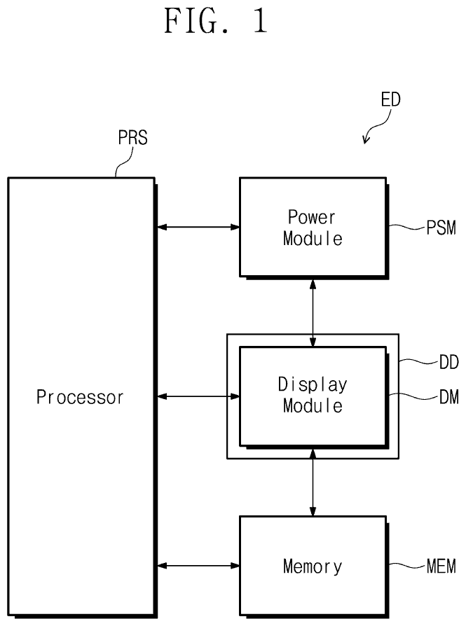

FIG. 1 is a block diagram of an electronic device according to an embodiment of the inventive concept.

Referring to FIG. 1, an electronic device ED according to an embodiment may include a display device DD which provides images to a user, and further include a module or a device which has additional functions in addition to the display device DD. The electronic device ED according to an embodiment may include a display module DM, a processor PRS, a memory MEM, and a power module PSM, and the display device DD may include the display module DM.

The processor PRS may include at least one of a central processing unit (CPU), an application processor (AP), a graphic processing unit (GPU), a communication processor (CP), an image signal processor (ISP), or a controller. The processor PRS may process image signals and provide the processed image signals to the display device DD, and the display device DD may generate images corresponding to the image signals.

In an embodiment, the processor PRS may be divided into two or more parts from a functional or structural viewpoint. For example, the processor PRS may include a main processor in a form of a first driver chip including a central processing unit, and an auxiliary processor in a form of a second driver chip including a controller which receives image signals from the main processor and processes the image signals so as to be suitable for an interface specification for the display module DM.

The memory MEM may store data information supportive of an operation of the processor PRS or the display module DM. In an example in which the processor PRS executes an application stored in the memory MEM, image data signals and/or input control signals are transmitted to the display module DM, and the display module DM may process the transmitted signals and output image information through a display screen.

The power module PSM may include a power supply module, such as a power adapter or a battery device, and a power conversion module which converts a power supplied by the power supply module to generate a power supportive of an operation of the electronic device ED. The power module PSM may supply power to the display module DM and the processor PRS.

At least one of components of the above-described electronic device ED may be included in the display device DD according to the above-described embodiments. In some aspects, some of the individual modules which are functionally included in one module may be included in the display device DD, and other modules may also be provided separately from the display device DD. For example, the display device DD may include the display module DM, and the processor PRS, the memory MEM, and the power module PSM may be provided in the form of other devices within the electronic device ED other than the display device DD.

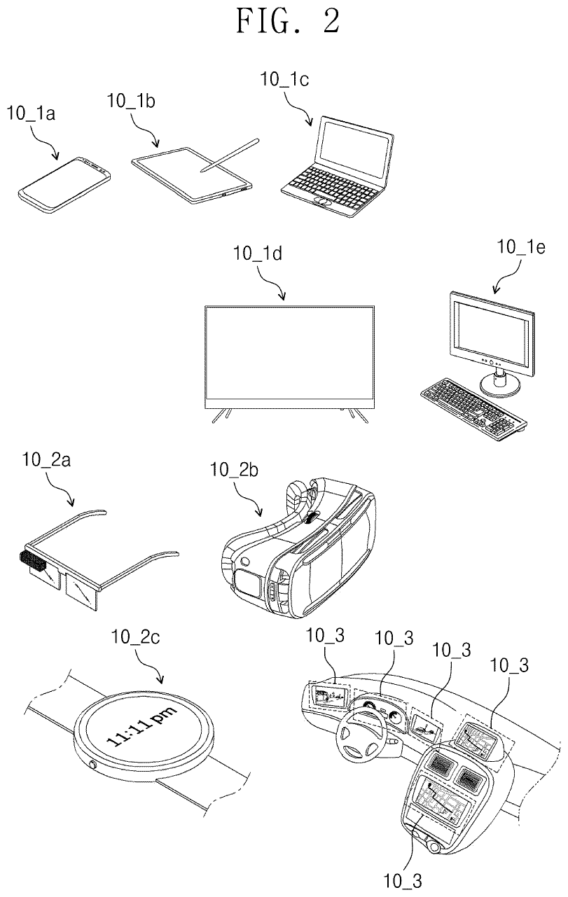

FIG. 2 is a schematic view of each of electronic devices according to various embodiments.

Referring to FIG. 2, the display device DD (see FIG. 1) according to an embodiment of the inventive concept may be applied to various electronic devices. For example, the various electronic devices provided with the display device DD according to an embodiment may include electronic devices for displaying images, such as a smart phone 10_1a, a tablet computer 10_1b, a laptop computer 10_1c, a television 10_1d, or a desktop monitor 10_1e.

In some aspects, the various electronic devices provided with the display device DD according to an embodiment may include wearable electronic devices, such as a smart glasses 10_2a, a head mounted display 10_2b, or a smart watch 10_2c. Furthermore, the various electronic devices provided with the display device DD according to an embodiment may include automobile electronic devices 10_3 such as, for example, a center information display (CID) disposed on an instrument panel, a center fascia, or a dashboard of a car, and a room mirror display.

Hereinafter, an electronic device ED will be exemplarily illustrated as the smart phone 10_1a.

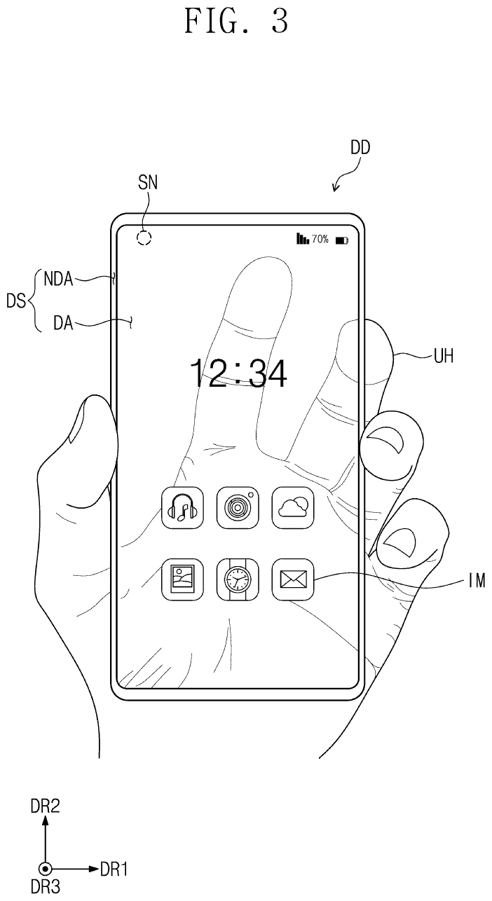

FIG. 3 is a perspective view of an electronic device according to an embodiment of the inventive concept.

Referring to FIG. 3, an electronic device ED according to an embodiment of the inventive concept may have a rectangular shape which has short sides extending in a first direction DR1 and long sides extending in a second direction DR2 crossing the first direction. However, embodiments of the present disclosure are not limited thereto, and the electronic device ED may have various shapes, such as a circular and polygonal shape.

Hereinafter, a third direction DR3 is defined as a direction, which is substantially perpendicular to a plane defined by the first direction DR1 and the second direction DR2. In some aspects, in this specification, the wording “when viewed on a plane” may be defined as a state when viewed in the third direction DR3.

An upper surface of the electronic device ED may be defined as a display surface DS, and the display surface DS may have a flat surface defined by the first direction DR1 and the second direction DR2. Images IM generated from the electronic device ED through the display surface DS may be provided to users.

The display surface DS may include a display region DA and a non-display region NDA around the display region DA. The display region DA may display the images IM, and the non-display region NDA may not display the images IM. The non-display region NDA may surround the display region DA and define a border of the electronic device ED which is printed in a predetermined color.

Although not illustrated, the display surface DS may be further defined on a rear surface of the electronic device ED. In this case, the images IM may also be displayed on the rear surface of the electronic device ED.

A user may view the images IM displayed on the display surface DS, as well as may further view objects or images positioned at the rear of the electronic device ED. For example, as illustrated in FIG. 3, a user's hand UH positioned at the rear of the electronic device ED may be visible.

The electronic device ED may include at least one sensor region SN. The sensor region SN may be adjacent to the border of the electronic device ED. The sensor region SN may be disposed in the display region DA adjacent to the non-display region NDA.

Although not illustrated, external light may pass through the sensor region SN and be provided to a sensor disposed below the sensor region SN. For example, the sensor may be a proximity sensor, but a type of sensor is not limited thereto, and may be another type of sensor, such as an adjacent sensor. The sensor may be provided in plurality.

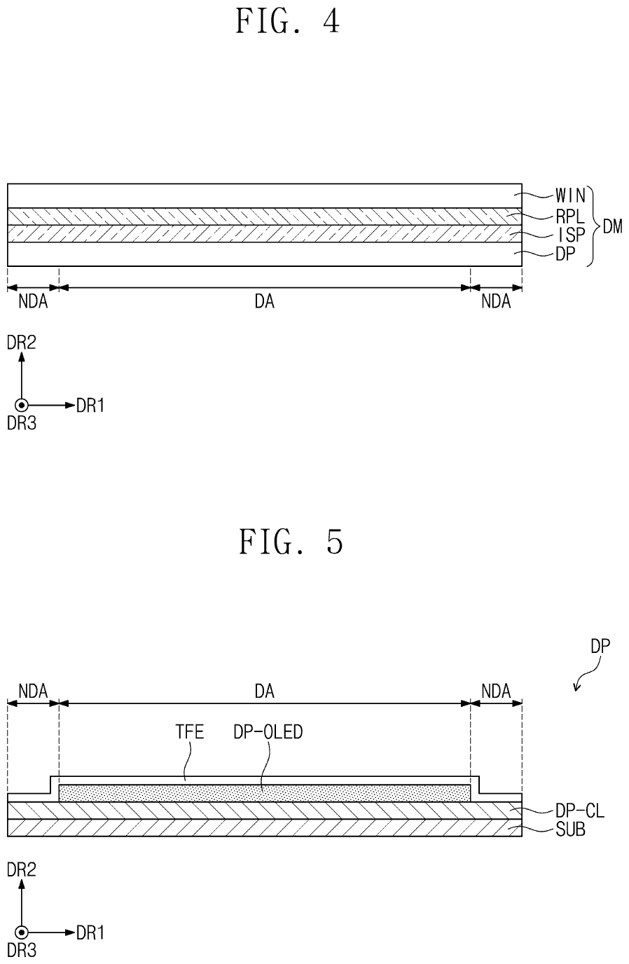

FIG. 4 is a schematic cross-sectional view of a display module.

A display module DM of FIG. 4 is not illustrated in FIG. 3, but may be included in the electronic device ED of FIG. 3.

Referring to FIG. 4, the display module DM may include a display panel DP, an input-sensing unit ISP, an anti-reflection layer RPL, and a window WIN.

The display panel DP may be transparent. For example, the display panel DP of FIG. 4 may be a light-emitting display panel, but is not particularly limited. For example, the display panel DP may be an organic light-emitting display panel or an inorganic light-emitting display panel. A light-emitting layer of the organic light-emitting display panel may include organic light-emitting materials. A light-emitting layer of the inorganic light-emitting display panel may include quantum dots, quantum rods, or the like. Hereinafter, the display panel DP is described as an organic light-emitting display panel.

The input-sensing unit ISP may be disposed on the display panel DP. The input-sensing unit ISP may include a plurality of sensor units (not illustrated) for sensing an external input in a capacitive manner. The input-sensing unit ISP may be manufactured directly on the display panel DP when the display module DM is manufactured. However, embodiments of the present disclosure are not limited thereto. The input-sensing unit ISP is manufactured as a panel separately from the display panel DP, and then may be attached to the display panel DP via an adhesive layer.

The anti-reflection layer RPL may be disposed on the input-sensing unit ISP. The anti-reflection layer RPL may be formed directly on the input-sensing unit ISP or coupled to the input-sensing unit ISP via an adhesive layer. The anti-reflection layer RPL may be defined as an external light anti-reflection film. The anti-reflection layer RPL may reduce reflectance for external light which enters the display panel DP from above the electronic device ED.

When external light propagating toward the display panel DP is reflected at the display panel DP and is re-provided to an external user, the external light may be visible to a user as if reflected from a mirror. In order to prevent this phenomenon, the anti-reflection layer RPL may include, for example, a plurality of color filters which display colors same as those of pixels of the transparent display panel DP.

The color filters may filter the external light with colors same as those of pixels. In this case, the external light may not be viewed by a user. However, embodiments of the present disclosure are not limited thereto, and the anti-reflection layer RPL may include a polarization film for reducing reflectance for external light. The polarization film may include a retarder and/or a polarizer.

The window WIN may be disposed on the anti-reflection layer RPL. The window WIN may be formed directly on the anti-reflection layer RPL or be coupled to the anti-reflection layer RPL via an adhesive layer. The window WIN may protect the transparent display panel DP, the input-sensing unit ISP, and the anti-reflection layer RPL against external scratches and impacts.

FIG. 5 exemplarily illustrates a cross-sectional view of the display panel illustrated in FIG. 4.

For example, FIG. 5 illustrates a cross section of a display panel DP when viewed in the second direction DR2.

Referring to FIG. 5, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display region DA and a non-display region NDA around the display region DA. The substrate SUB may include glass or a flexible plastic material such as, for example, polyimide (PI). The display element layer DP-OLED may be disposed in the display region DA.

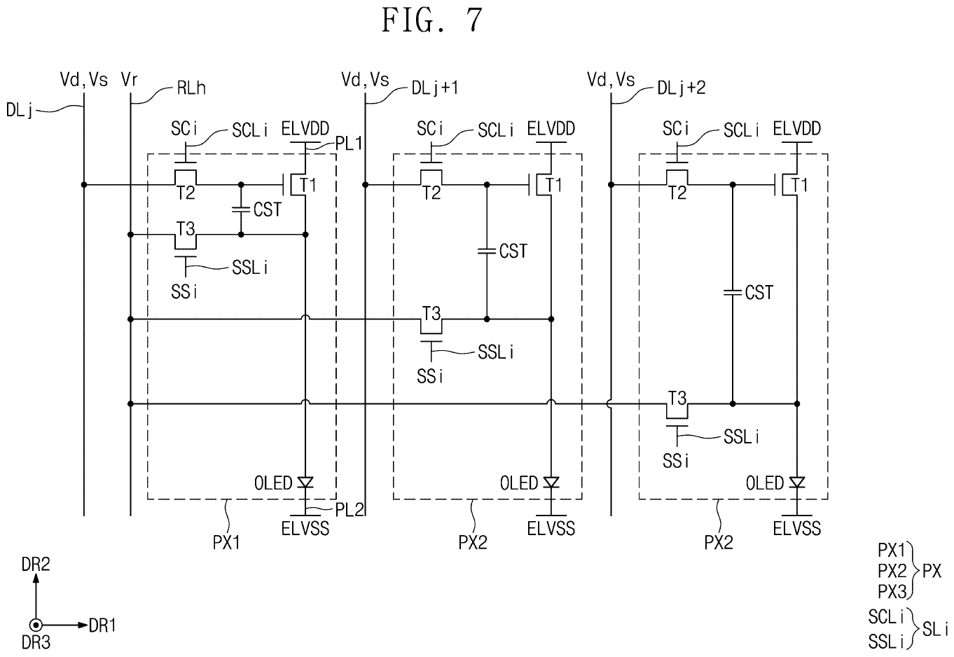

A plurality of pixels may be disposed on the circuit element layer DP-CL and the display element layer DP-OLED. The pixels may each include a transistor disposed on the circuit element layer DP-CL, and a light-emitting element which is disposed on the display element layer DP-OLED and is connected to the transistor. The configuration of the pixels will be described in detail with reference to FIG. 7.

The thin-film encapsulation layer TFE may be disposed on the circuit element layer DP-CL and cover the display element layer DP-OLED. The thin-film encapsulation layer TFE may protect pixels against moisture, oxygen, and external foreign substances.

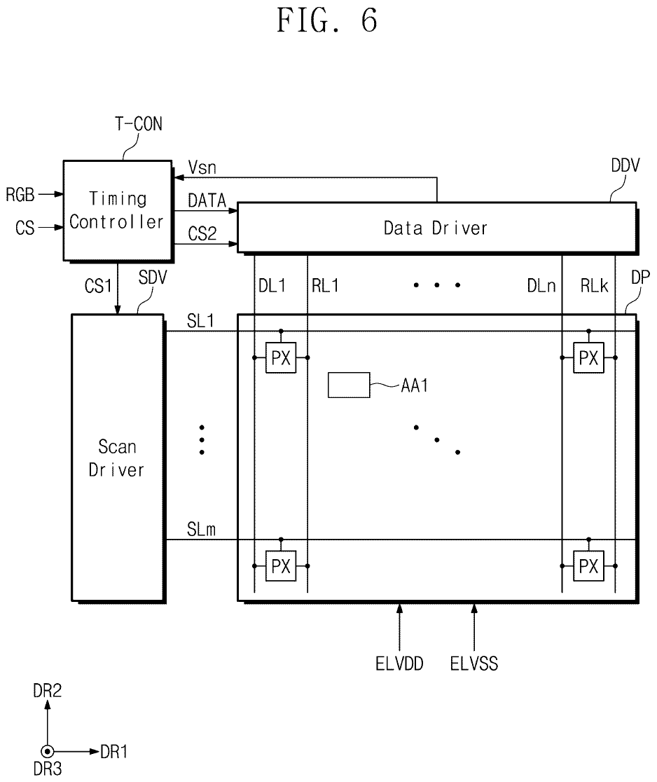

FIG. 6 is a block diagram of the display module illustrated in FIG. 4.

Referring to FIG. 6, the display module DM may include a display panel DP, a scan driver SDV, a data driver DDV, and a timing controller T-CON. The display panel DP may include a plurality of pixels PX, a plurality of scan lines SL1 to SLm, a plurality of data lines DL1 to DLn, and a plurality of reference lines RL1 to RLk. k, m, and n are natural numbers.

The scan lines SL1 to SLm may extend in the first direction DR1 to be connected to the pixels PX and the scan driver SDV. The data lines DL1 to DLn and the reference lines RL1 to RLk may extend in the second direction DR2 to be connected to the pixels PX and the data driver DDV.

A first voltage ELVDD and a second voltage ELVSS may be provided to the display panel DP. The first voltage ELVDD may have a higher level than the second voltage ELVSS. The first voltage ELVDD and the second voltage ELVSS may be applied to the pixels PX.

The timing controller T-CON may receive image signals RGB and a control signal CS from the above-described processor PRS. The timing controller T-CON may generate pieces of image data DATA by converting data formats of the image signals RGB to be suitable for an interface specification with the data driver DDV. The timing controller T-CON may provide the data driver DDV with the pieces of image data DATA the data format of which is converted.

The timing controller T-CON may generate and output a scan control signal CS1 and a data control signal CS2 in response to the control signal CS provided from the outside. The scan control signal CS1 may be provided to the scan driver SDV, and the data control signal CS2 may be provided to the data driver DDV.

The scan driver SDV may generate a plurality of scan signals in response to the scan control signal CS1. The scan signals may be applied to the pixels PX via the scan lines SL1 to SLm.

The data driver DDV may generate a plurality of data voltages corresponding to the pieces of image data DATA in response to the data control signal CS2. The data voltages may be applied to the pixels PX via the data lines DL1 to DLn.

The pixels PX may receive data voltages in response to the scan signals. The pixels PX may display images by emitting light having luminance corresponding to the data voltages.

The data driver DDV may apply sensing data voltages and reference voltages to the pixels PX. The sensing data voltages may be applied to the pixels PX via the data lines DL1 to DLn. The reference voltages may be applied to the pixels PX via the reference lines RL1 to RLk.

Sensing voltages Vsn sensed at the pixels PX according to the sensing data voltages and the reference voltages may be provided to the data driver DDV via the reference lines RL1 to RLk. The timing controller T-CON may compensate data voltages applied to bright pixels adjacent to defective pixels according to the sensing voltages Vsn.

FIG. 7 is a view illustrating an equivalent circuit of a first pixel, a second pixel, and a third pixel included among the pixels illustrated in FIG. 6.

Referring to FIG. 7, pixels PX may include a first pixel PX1, a second pixel PX2, and a third pixel PX3. The first pixel PX1, the second pixel PX2, and the third pixel PX3 may be arranged in the first direction DR1. The first pixel PX1, the second pixel PX2, and the third pixel PX3 may respectively emit light of different colors. For example, the first pixel PX1 may emit red light, the second pixel PX2 may emit blue light, and the third pixel PX3 may emit green light.

The first direction DR1 may correspond to a row, and the second direction DR2 may correspond to a column. For example, FIG. 6 illustrates that the first pixel PX1, the second pixel PX2, and the third pixel PX3 are disposed in an ith row, a jth column, a (j+1)th column, and a (j+2)th column. i and j are natural numbers. Although not illustrated, the first pixel PX1, the second pixel PX2, and the third pixel PX3 may each be provided in plurality to the display panel DP.

The first pixel PX1 may be connected to a jth data line DLj, an ith scan line SLi, a hth reference line RLh, a first power line PL1, and a second power line PL2. The second pixel PX2 may be connected to a (j+1)th data line DLj+1, the ith scan line SLi, the hth reference line RLh, the first power line PL1, and the second power line PL2. The third pixel PX3 may be connected to a (j+2)th data line DLj+2, the ith scan line SLi, the hth reference line RLh, the first power line PL1, and the second power line PL2.

The first pixel PX1, the second pixel PX2, and the third pixel PX3 may be respectively connected to the jth data line DLj, the (j+1)th data line DLj+1, and the (j+2)th data line DLj+2. The first pixel PX1, the second pixel PX2, and the third pixel PX3 may be connected to the hth reference line RLh in common.

The jth data line DLj, the (j+1)th data line DLj+1, and the (j+2)th data line DLj+2 may each receive a data voltage Vd and a sensing data voltage Vs. The hth reference line RLh may receive a reference voltage Vr.

The ith scan line SLi may receive ith scan signals SCi and SSi. The ith scan line SLi may include an ith write scan line SCLi and an ith sampling scan line SSLi. The ith scan signals SCi and SSi may include an ith write scan signal SCi and an ith sampling scan signal SSi. The ith write scan line SCLi may receive the ith write scan signal SCi. The ith sampling scan line SSLi may receive the ith sampling scan signal SSi.

The first power line PL1 may receive a first voltage ELVDD. The second power line PL2 may receive a second voltage ELVSS.

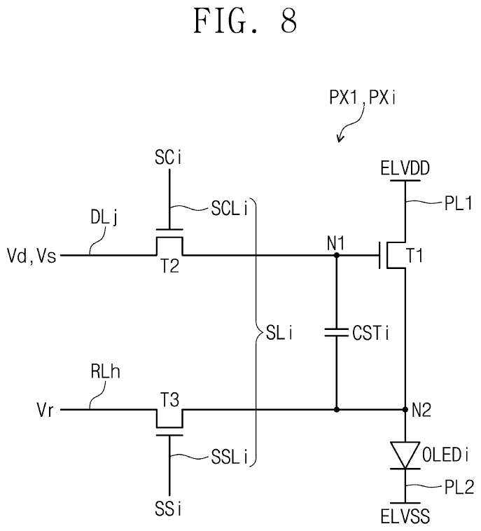

The first pixel PX1, the second pixel PX2, and the third pixel PX3 may each include a plurality of transistors T1, T2, and T3, a capacitor CST, and a light-emitting element OLED. The first pixel PX1, the second pixel PX2, and the third pixel PX3 have the same configuration, and thus a circuit configuration of the first pixel PX1 will be exemplarily described herein with reference to FIG. 8.

FIG. 8 is an equivalent circuit diagram of the first pixel illustrated in FIG. 7.

Hereinafter, in FIG. 8, the first pixel PX1 is defined as an ith pixel PXi disposed in an ith row, the light-emitting element OLED is defined as an ith light-emitting element OLEDi, and the capacitor CST is defined as an ith capacitor CSTi.

Referring to FIG. 8, the ith pixel PXi may be connected to a jth data line DLj, a hth reference line RLh, an ith write scan line SCLi, and an ith sampling scan line SSLi.

The ith pixel PXi may include the ith light-emitting element OLEDi, a plurality of transistors T1, T2, and T3, and the ith capacitor CSTi. The transistors T1, T2, and T2 may include a first transistor T1, a second transistor T2, and a third transistor T3.

The first, second, and third transistors T1, T2, and T3 may be NMOS transistors, but are not limited thereto, and may be PMOS transistors. The first, second, and third transistors T1, T2, and T2 may each include a source electrode, a drain electrode, and a gate electrode. Hereinafter, in this specification, for convenience of the description, one among the source electrode and the drain electrode is defined as a first electrode, and the other is defined as a second electrode. Additionally, the gate electrode is defined as a control electrode.

The ith light-emitting element OLEDi may be an organic light-emitting element including an anode and a cathode. The anode of the ith light-emitting element OLEDi may receive the first voltage ELVDD via the first transistor T1, and the cathode of the ith light-emitting element OLEDi may receive the second voltage ELVSS. The ith light-emitting element OLEDi may receive the first voltage ELVDD and the second voltage ELVSS and emit light.

The first transistor T1 may include a first electrode which is connected to a first power line PL1 and receives the first voltage ELVDD, a control electrode which is connected to a first node N1, and a second electrode which is connected to a second node N2. The first transistor T1 may be switched by the voltage of the first node N1.

The anode of the ith light-emitting element OLEDi may be connected to the second node N2. The cathode of the ith light-emitting element OLEDi may be connected to the second power line PL2 and may receive the second voltage ELVSS.

The second transistor T2 may include a first electrode which is connected to the jth data line DLj, a second electrode which is connected to the first node N1, and a control electrode which is connected to the ith write scan line SCLi. The second transistor T2 may be switched by an ith write scan signal SCi applied via the ith write scan line SCLi. A data voltage Vd and a sensing data voltage Vs may be applied to the second transistor T2 via the jth data line DLj.

The third transistor T3 may include a first electrode which is connected to the hth reference line RLh, a second electrode which is connected to the second node N2, and a control electrode which is connected to the ith sampling scan line SSLi. The third transistor T3 may be switched by an ith sampling scan signal SSi applied via the ith sampling scan line SSLi. A reference voltage Vr may be applied to the third transistor T3 via the hth reference line RLh.

The ith capacitor CSTi may include the first electrode which is connected to the first node N1, and the second electrode which is connected to the second node N2. The ith capacitor CSTi may be connected to a control electrode of the first transistor T1, and the anode of the ith light-emitting element OLEDi via the first and second nodes N1 and N2.

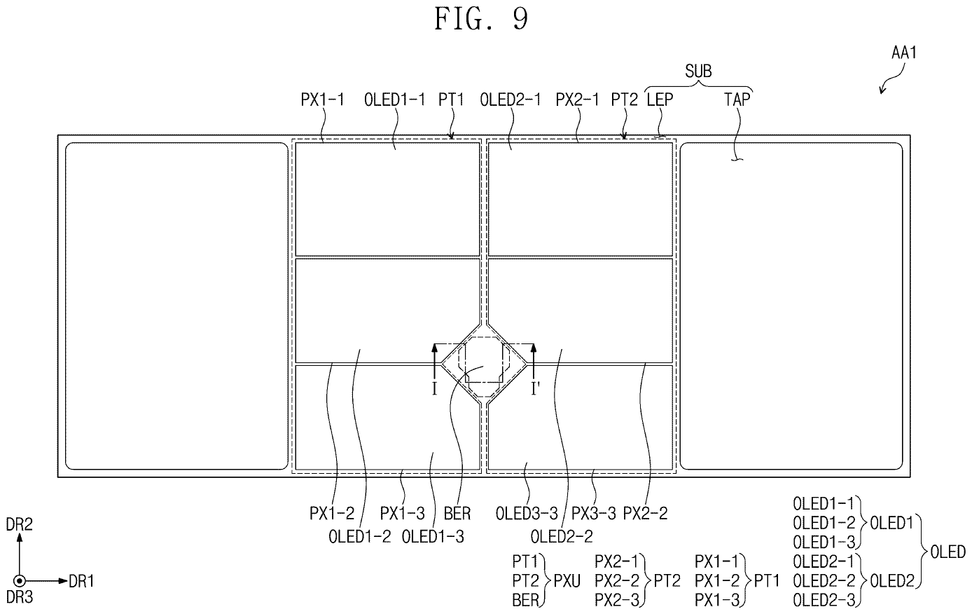

FIG. 9 is an enlarged plan view of the first region AA1 illustrated in FIG. 6.

Among components illustrated in FIG. 9, the description of components which are described with reference to the above-described drawings and are identical or similar to the described components will be omitted or abbreviated.

Referring to FIG. 9, the substrate SUB (see FIG. 5) of the display panel DP (see FIG. 6) may include a plurality of transmissive parts TAP and a display part LEP. The transmissive parts TAP may be disposed on both sides of the display part LEP, which are opposite to each other in the first direction DR1. When viewed on a plane, the transmissive parts TAP may have a quadrangular shape defined by the first direction DR1 and the second direction DR2. When viewed on a plane, the transmissive parts TAP may have the same area. A light-emitting element OLED may not be disposed in the transmissive parts TAP.

The display part LEP may be disposed between the transmissive parts TAP. The display part LEP may have a quadrangular shape defined by the first direction DR1 and the second direction DR2. For example, FIG. 9 illustrates that the area of the display part LEP is greater than the areas of the transmissive parts TAP, but the area of the display part LEP may be smaller than or equal to the areas of the transmissive parts TAP.

The display panel DP (see FIG. 6) may include a pixel unit PXU. The pixel unit PXU may be disposed in the display part LEP. The pixel unit PXU may be disposed between the transmissive parts TAP.

The pixel unit PXU may include a first portion PT1, a second portion PT2, and a bus electrode BER. The first portion PT1 and the second portion PT2 may be arranged in the first direction DR1. The first portion PT1 and the second portion PT2 may be symmetrical to each other with respect to the first direction DR1. The first portion PT1 and the second portion PT2 may be symmetrical to each other with respect to an axis parallel to the second direction DR2. The first portion PT1 may be defined as the first pixel PX1 (see FIG. 7), the second pixel PX2 (see FIG. 7), and the third pixel PX3 (see FIG. 7), which are disposed on a left side of the bus electrode BER. The second portion PT2 may be defined as the first pixel PX1 (see FIG. 7), the second pixel PX2 (see FIG. 7), and the third pixel PX3 (see FIG. 7), which are disposed on a right side of the bus electrode BER.

Referring to FIGS. 7 and 9, the first portion PT1 may include a (1-1)-th pixel PX1-1, a (1-2)-th pixel PX1-2, and a (1-3)-th pixel PX1-3. The (1-1)-th pixel PX1-1, the (1-2)-th pixel PX1-2, and the (1-3)-th pixel PX1-3 may be arranged in the second direction DR2. Substantially, the (1-1)-th pixel PX1-1 may be the same as the first pixel PX1. The (1-2)-th pixel PX1-2 may be the same as the second pixel PX2. The (1-3)-th pixel PX1-3 may be the same as the third pixel PX3.

FIG. 9 exemplarily illustrates one (1-1)-th pixel PX1-1, one (1-2)-th pixel PX1-2, and one (1-3)-th pixel PX1-3, but embodiments of the present disclosure are not limited thereto, and at least one pixel among the (1-1)-th pixel PX1-1, the (1-2)-th pixel PX1-2, and the (1-3)-th pixel PX1-3 may be provided in plurality.

The (1-1)-th pixel PX1-1 may include a (1-1)-th light-emitting element OLED1-1, the plurality of transistors T1, T2, and T3, and the capacitor CST. The (1-2)-th pixel PX1-2 may include a (1-2)-th light-emitting element OLED1-2, the plurality of transistors T1, T2, and T3, and the capacitor CST (see FIG. 7). The (1-3)-th pixel PX1-3 may include a (1-3)-th light-emitting element OLED1-3, the plurality of transistors T1, T2, and T3 (see FIG. 7), and the capacitor CST (see FIG. 7).

For example, the (1-1)-th light-emitting element OLED1-1 may have a rectangular shape. The (1-2)-th light-emitting element OLED1-2 and the (1-3)-th light-emitting element OLED1-3 may have a trapezoidal shape. The (1-1)-th light-emitting element OLED1-1 may emit red light, the (1-2)-th light-emitting element OLED1-2 may emit green light, and the (1-3)-th light-emitting element OLED1-3 may emit blue light.

Hereinafter, the (1-1)-th light-emitting element OLED1-1, the (1-2)-th light-emitting element OLED1-2, and the (1-3)-th light-emitting element OLED1-3 which are disposed on the left side of the bus electrode BER may be defined as first light-emitting elements OLED1. In some aspects, the transistors T1, T2, and T3 which are disposed on the left side of the bus electrode BER may be defined as first pixel transistors T1, T2, and T3. The connection of the first light-emitting elements OLED1 and the first pixel transistors T1, T2, and T3 is described above, and thus the description will be omitted.

The second portion PT2 may include a (2-1)-th pixel PX2-1, a (2-2)-th pixel PX2-2, and a (2-3)-th pixel PX2-3. The (2-1)-th pixel PX2-1, the (2-2)-th pixel PX2-2, and the (2-3)-th pixel PX2-3 may be arranged in the second direction DR2. Substantially, the (2-1)-th pixel PX2-1 may be the same as the first pixel PX1. The (2-2)-th pixel PX2-2 may be the same as the second pixel PX2. The (2-3)-th pixel PX2-3 may be the same as the third pixel PX3.

FIG. 9 exemplarily illustrates one (2-1)-th pixel PX2-1, one (2-2)-th pixel PX2-2, and one (2-3)-th pixel PX2-3, but embodiments of the present disclosure are not limited thereto, and at least one pixel among the (2-1)-th pixel PX2-1, the (2-2)-th pixel PX2-2, and the (2-3)-th pixel PX2-3 may be provided in plurality.

The (2-1)-th pixel PX2-1 may include a (2-1)-th light-emitting element OLED2-1, the plurality of transistors T1, T2, and T3 (see FIG. 7), and the capacitor CST (see FIG. 7). The (2-2)-th pixel PX2-2 may include a (2-2)-th light-emitting element OLED2-2, the plurality of transistors T1, T2, and T3 (see FIG. 7), and the capacitor CST (see FIG. 7). The (2-3)-th pixel PX2-3 may include a (2-3)-th light-emitting element OLED2-3, the plurality of transistors T1, T2, and T3 (see FIG. 7), and the capacitor CST (see FIG. 7).

For example, the (2-1)-th light-emitting element OLED2-1 may have a rectangular shape. The (2-2)-th light-emitting element OLED2-2 and the (2-3)-th light-emitting element OLED2-3 may have a trapezoidal shape. The (2-1)-th light-emitting element OLED2-1 may emit red light, the (2-2)-th light-emitting element OLED2-2 may emit green light, and the (2-3)-th light-emitting element OLED2-3 may emit blue light.

The (1-1)-th light-emitting element OLED1-1 and the (2-1)-th light-emitting element OLED2-1 may be arranged in the first direction DR1. The (1-2)-th light-emitting element OLED1-2 and the (2-2)-th light-emitting element OLED2-2 may be arranged in the first direction DR1. The (1-3)-th light-emitting element OLED1-3 and the (2-3)-th light-emitting element OLED2-3 may be arranged in the first direction DR1.

Hereinafter, the (2-1)-th light-emitting element OLED2-1, the (2-2)-th light-emitting element OLED2-2, and the (2-3)-th light-emitting element OLED2-3 which are disposed on the right side of the bus electrode BER may be defined as second light-emitting elements OLED2. In some aspects, the transistors T1, T2, and T3 (see FIG. 7) which are disposed on the right side of the bus electrode BER may be defined as second pixel transistors T1, T2, and T3 (see FIG. 7). The connection of the second light-emitting elements OLED2 and the second pixel transistors T1, T2, and T3 is described herein, and thus the description will be omitted.

Referring to FIG. 9, the bus electrode BER may be disposed between the first portion PT1 and the second portion PT2. The (1-2)-th light-emitting element OELD1-2, the (1-3)-th light-emitting element OLED1-3, the (2-2)-th light-emitting element OLED2-2, and the (2-3)-th light-emitting element OLED2-3 may surround the bus electrode BER. An edge of the (1-2)-th light-emitting element OELD1-2, an edge of the (1-3)-th light-emitting element OLED1-3, an edge of the (2-2)-th light-emitting element OLED2-2, and an edge of the (2-3)-th light-emitting element OLED2-3 which are adjacent to the bus electrode BER may have a shape corresponding to the bus electrode BER.

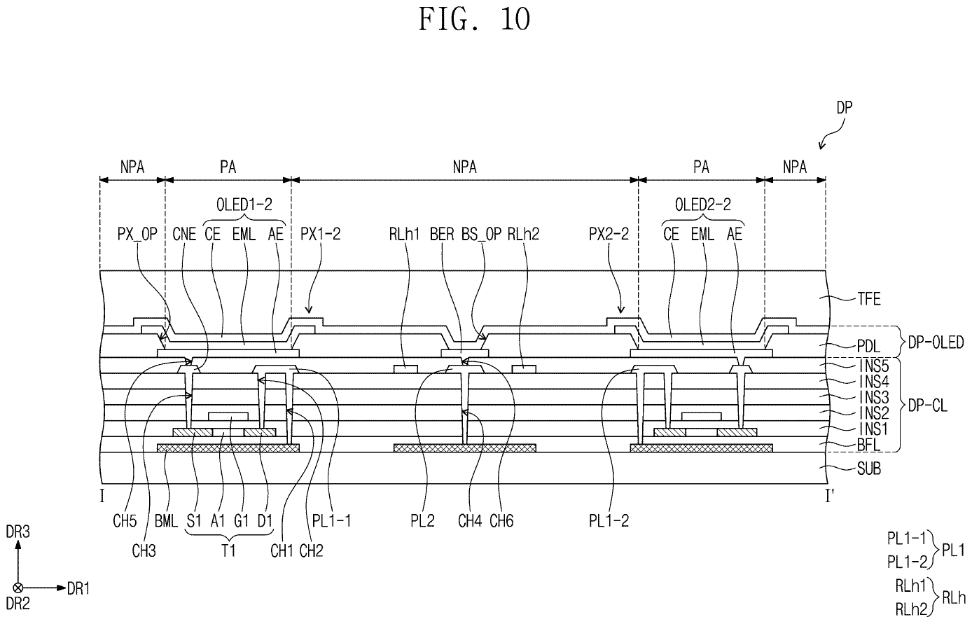

FIG. 10 is a cross-sectional view of a display part taken along line I-I′ illustrated in FIG. 9.

For example, in FIG. 10, a (2-2)-th pixel PX2-2 is substantially identical or similar to a (1-2)-th pixel PX1-2 except for being symmetrical to each other with respect to the first direction DR1. Accordingly, the (2-2)-th pixel PX2-2 is not described, and the description will be focused on the (1-2)-th pixel PX1-2.

FIG. 10 exemplarily illustrates the (1-2)-th pixel PX1-2 and the (2-2)-th pixel PX2-2, but a (1-1)-th pixel PX1-1, a (1-3)-th pixel PX1-3, a (2-1)-th pixel PX2-1, and a (2-3)-th pixel PX2-3 may also have the substantially same configuration.

Among components illustrated in FIG. 10, the description of components which are described with reference to the above-described drawings and are identical or similar to the described components will be omitted or abbreviated.

Referring to FIGS. 9 and 10, a planar region of each of the pixels PX may include a light-emitting region PA and a non-light-emitting region NPA around the light-emitting region PA. The light-emitting elements OLED may be disposed in the light-emitting region PA.

A display panel DP may include a lower metal layer BML, a buffer layer BFL and first to fifth insulating layers INS1 to INS5. The lower metal layer BML may be disposed on a substrate SUB. The lower metal layer BML may overlap a first transistor T1. Although not illustrated, a constant voltage may be applied to the lower metal layer BML. In an example in which the constant voltage is applied to the lower metal layer BML, a threshold voltage value of the first transistor T1 disposed on the lower metal layer BML may be maintained unchanged.

In some aspects, the lower metal layer BML may block light from entering the first transistor T1 from below the lower metal layer BML. The lower metal layer BML may include reflective metal. The lower metal layer BML may be omitted.

A buffer layer BFL may be disposed on the substrate SUB, and the buffer layer BFL may be an inorganic layer. The buffer layer BFL may cover the lower metal layer BML. Semiconductor layers S1, A1, and D1 of the first transistor T1 may be disposed on the buffer layer BFL. The semiconductor layers S1, A1, and D1 may include polysilicon. However, embodiments of the present disclosure are not limited thereto, and the semiconductor layers S1, A1, and D1 may include amorphous silicon.

The semiconductor layers S1, A1, and D1 may be doped with an N-type dopant or a P-type dopant. The semiconductor layers S1, A1, and D1 may include a highly-doped region and a lightly-doped region. The conductivity of the highly-doped region is greater than the conductivity of the lightly-doped region, and may substantially serve as a source electrode and drain electrode of each of the first transistors T1. The lightly-doped region may substantially correspond to an active (or a channel) of each of the first transistors T1.

A first source region S1, a first channel region A1, and a first drain region D1 of the first transistor T1 may be formed from the semiconductor layers S1, A1, and D1. The first channel region A1 may be disposed between the first source region S1 and the first drain region D1.

The first insulating layer INS1 may be disposed on the buffer layer BFL and cover the semiconductor layers S1, A1, and D1. A first gate electrode G1 (or a control electrode) of each of the first transistors T1 may be disposed on the first insulating layer INS1.

Although not illustrated, the configuration of the source region, the channel region, the drain region, and the gate electrode of each of the second and third transistors T2 and T3 (see FIG. 7) may be substantially identical or similar to those of the first transistor T1.

The second insulating layer INS2 may be disposed on the first insulating layer INS1 and cover the first gate electrode G1. The third insulating layer INS3 may be disposed on the second insulating layer INS2. The fourth insulating layer INS4 may be disposed on the third insulating layer INS3.

A first power line PL1 may be disposed on the fourth insulating layer INS4. The first power line PL1 may be connected to the lower metal layer BML via a first contact hole CN1 which is defined in the buffer layer BFL, and the first to fourth insulating layers INS1 to INS4. The first power line PL1 may be connected to the first drain region D1 of the first transistor T1 via a second contact hole CH2 which is defined in the first to fourth insulating layers INS1 to INS4.

The first power line PL1 may include a (1-1)-th power line PL1-1 and a (1-2)-th power line PL1-2. Hereinafter, the (1-1)-th power line PL1-1 may be defined as the first power line PL1 which is connected to the first light-emitting elements OLED1, and the (1-2)-th power line PL1-2 may be defined as the first power line PL1 which is connected to the second light-emitting elements OLED2.

The (1-1)-th power line PL1-1 may apply the first voltage ELVDD (see FIG. 7) to the (1-2)-th light-emitting element OLED1-2. Although not illustrated, the (1-1)-th power line PL1-1 may be connected to the (1-1)-th light-emitting element OLED1-1 and the (1-3)-th light-emitting element OLED1-3 and apply the first voltage ELVDD (see FIG. 7).

The (1-2)-th power line PL1-2 may apply the first voltage ELVDD (see FIG. 7) to the (2-2)-th light-emitting element OLED2-2. Although not illustrated, the (1-2)-th power line PL1-2 may be connected to the (2-1)-th light-emitting element OLED2-1 and the (2-3)-th light-emitting element OLED2-3 and apply the first voltage ELVDD (see FIG. 7).

A connection electrode CNE may be disposed on the fourth insulating layer INS4. The connection electrode CNE may be connected to the first source region S1 of the first transistor T1 via a third contact hole CN3 which is defined in the first to fourth insulating layers INS1 to INS4.

The second power line PL2 may be disposed on the fourth insulating layer INS4. The second power line PL2 may be spaced apart from the first power line PL1 in the first direction DR1. The second power line PL2 may be connected to the lower metal layer BML via a fourth contact hole CN4 which is defined in the buffer layer BFL, and the first to fourth insulating layers INS1 to INS4.

A hth reference line RLh may be disposed on the fourth insulating layer IN4. The hth reference line RLh may include a first reference line RLh1 and a second reference line RLh2. Although not illustrated, the first reference line RLh1 may be connected to the third transistor T3 (see FIG. 7) of the first portion PT1 and apply the reference voltage Vr (see FIG. 7). The second reference line RLh2 may be connected to the third transistor T3 (see FIG. 7) of the second portion PT2 and apply the reference voltage Vr (see FIG. 7).

The fifth insulating layer INS5 may be disposed on the hth reference line RLh, the first power line PL1, the connection electrode CNE, and the second power line PL2. The layers ranging from the buffer layer BFL to the fifth insulating layer INS5 may be defined as a circuit element layer DP-CL. The first insulating layer INS1 to the fifth insulating layer INS5 may be an inorganic layer or an organic layer.

A first electrode AE and a bus electrode BER may be disposed on the fifth insulating layer INS5. The first electrode AE may be referred to as an anode AE. The first electrode AE may be connected to the connection electrode CNE via a fifth contact hole CH5 which is defined in the fifth insulating layer INS5. The bus electrode BER may overlap the second power line PL2. The bus electrode BER may be connected to the second power line PL2 via a sixth contact hole CH6 which is defined in the fifth insulating layer INS5.

A pixel-defining film PDL may be disposed on the first electrode AE, the bus electrode BER, and the fifth insulating layer INS5. An opening PX_OP for exposing a predetermined portion of the first electrode AE may be defined in the pixel-defining film PDL. The pixel-defining film PDL may define a contact opening BS_OP for exposing a predetermined portion of the bus electrode BER. The pixel-defining film PDL may cover a border of the first electrode AE. The pixel-defining film PDL may cover a border of the bus electrode BER.

A light-emitting layer EML may be disposed on the first electrode AE. The light-emitting layer EML may be disposed in a region corresponding to the opening PX_OP. The light-emitting layer EML may include an organic material and/or an inorganic material. The light-emitting layer EML may generate light having one color of red, green, or blue.

Although not illustrated, a hole control layer may be further disposed between the first electrode AE and the light-emitting layer EML. The hole control layer may further include a hole transport layer and/or a hole injection layer.

A second electrode CE may be disposed on the light-emitting layer EML. The second electrode CE may be referred to as a cathode CE. The second electrode CE may be disposed in the pixels PX in common. That is, the second electrode CE may be disposed on the light-emitting layers EML of the pixels PX in common.

The second electrode CE may be disposed within the contact opening BS_OP. The second electrode CE may be in contact with the bus electrode BER, which is exposed by the pixel-defining film PDL to be outside within the contact opening BS_OP. Accordingly, the second electrode CE may be electrically connected to the second power line PL2. The second power line PL2 may apply a second voltage to the (1-2)-th light-emitting element OLED1-2 and the (2-2)-th light-emitting element OLED2-2.

Although not illustrated, the second power line PL2 may be connected to the (1-1)-th light-emitting element OLED1-1, the (1-3)-th light-emitting element OLED1-3, the (2-1)-th light-emitting element OLED2-1, and the (2-3)-th light-emitting element OLED2-3 and apply the second voltage ELVSS.

Although not illustrated, an electron control layer may be further disposed between the light-emitting layer EML and the second electrode CE. The electron control layer may further include an electron transport layer and/or an electron injection layer.

The first voltage ELVDD (see FIG. 7) may be applied to the first electrode AE, and the second voltage ELVSS (see FIG. 7) may be applied to the second electrode CE. Holes and electrons injected into the light-emitting layer EML are combined to form excitons, and the excitons transition to a ground state, such that the light-emitting element OLED may emit light. The light-emitting element OLED emits light, and thus an image may be displayed.

When the second power line PL2, which applies the second voltage to the first light-emitting elements OLED1, and the second power line PL2, which applies the second voltage to the second light-emitting elements OLED2, are separately disposed, an area of the display part LEP may be increased. Accordingly, areas of the transmissive parts TAP may be decreased.

However, according to an embodiment of the inventive concept, as the second voltage is applied to the first light-emitting elements OLED1 and the second light-emitting elements OLED2 via the second power line PL2, the area of the display part LEP may be decreased. Accordingly, the areas of the transmissive parts TAP may be increased.

In some aspects, when a plurality of the second power lines PL2 and a plurality of bus electrodes BER are provided, the second power lines PL2 and the bus electrodes BER may be disposed in a border of the display part LEP adjacent to the transmissive parts TAP. In the bus electrodes BER, both sides of the bus electrodes BER, opposed to each other in the first direction DR1 may be asymmetrical with respect to the first direction DR1 so as to prevent interference with the transmissive parts TAP. Among the both sides of the bus electrodes BER, opposed to each other in the first direction DR1, one side spaced apart from the transmissive parts TAP may protrude toward the first and second light-emitting elements OLED1 and OLED2. Accordingly, areas of the pixel openings PX_OP may be decreased, which may prevent the pixel openings PX_OP and the contact opening BS_OP from interfering with each other. Therefore, aperture ratios of the first and second light-emitting elements OLED1 and OLED2 may be reduced.

However, according to an embodiment of the inventive concept, the bus electrode BER may be disposed between the first portion P1 and the second portion PT2, and both sides opposed to each other in the first direction DR1 may have shapes which are symmetrical with each other. Accordingly, areas of the decreased pixel openings PX_OP may be decreased. Therefore, aperture ratios of the first light-emitting elements OLED1 and the second light-emitting elements OLED2 may be increased.

A thin-film encapsulation layer TFE may be disposed on the light-emitting element OLED. The thin-film encapsulation layer TFE may include an inorganic layer, an organic layer, and an inorganic layer which are sequentially stacked. The inorganic layer may include an inorganic material and protect pixels from moisture/oxygen. The organic layer may include an organic material and protect the pixels PX against foreign substances such as, for example, dust particles.

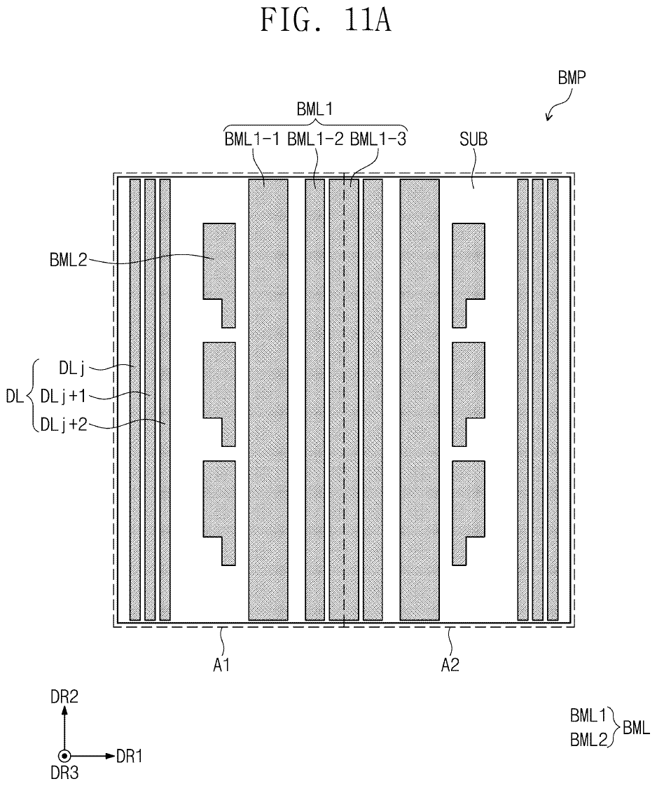

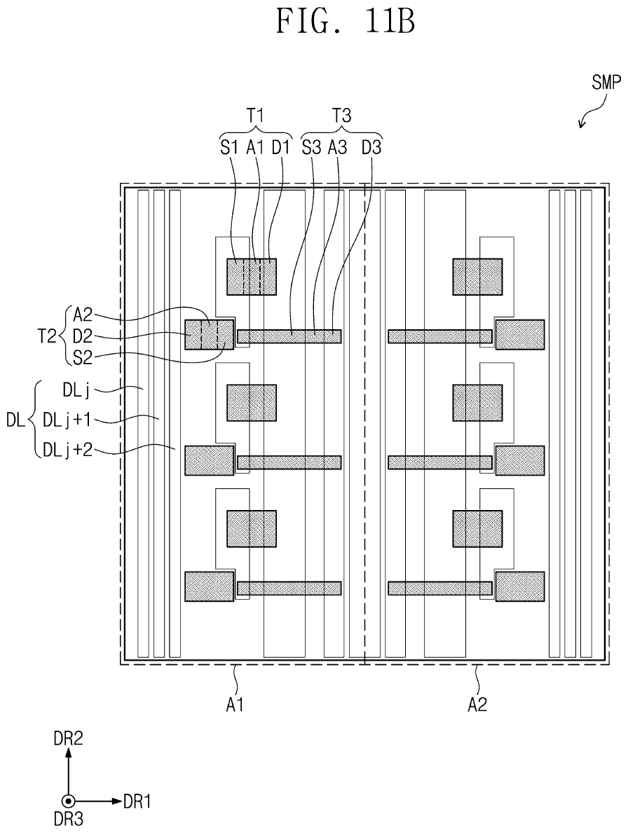

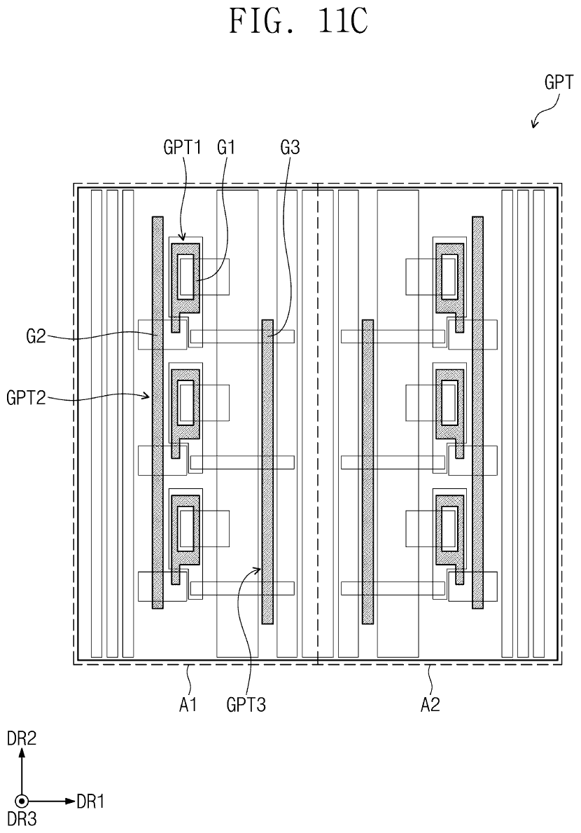

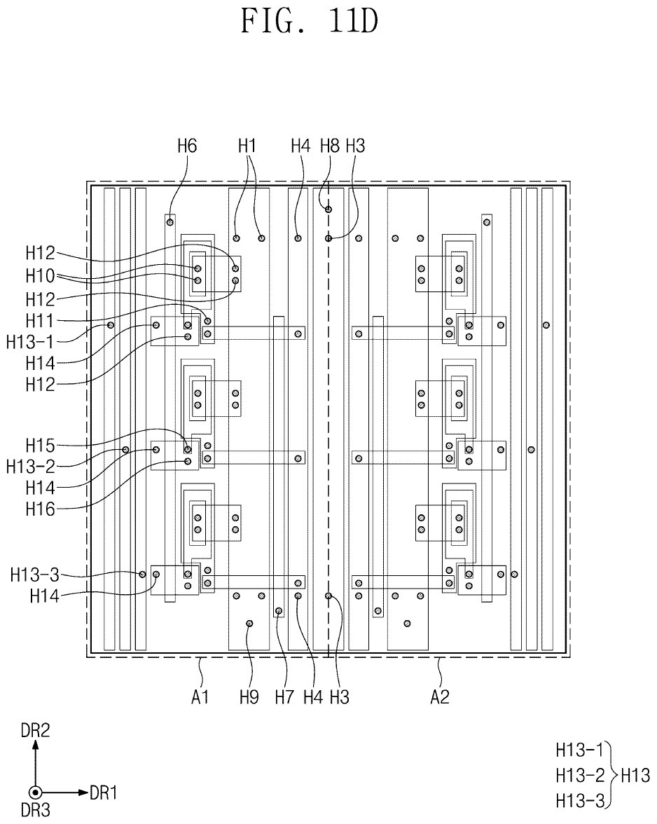

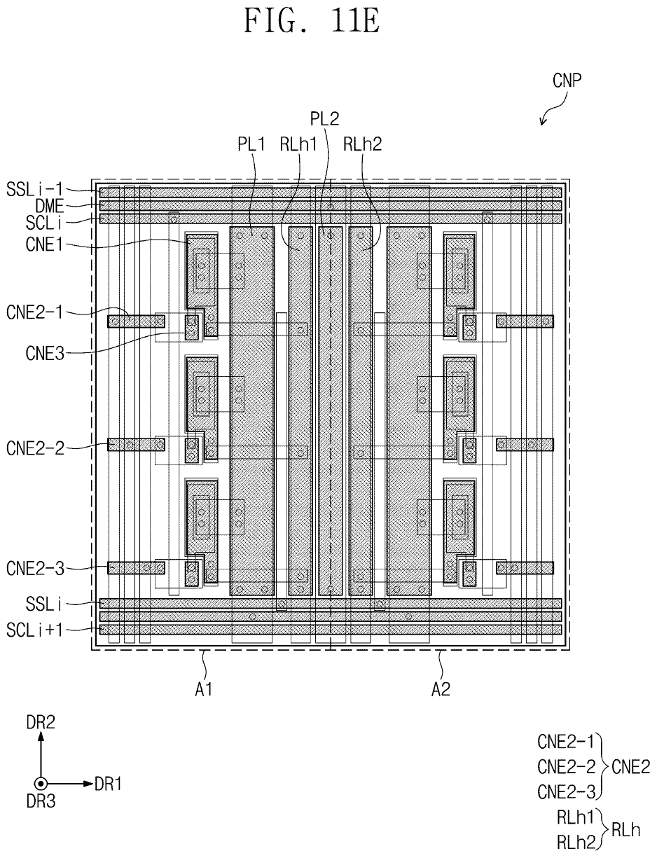

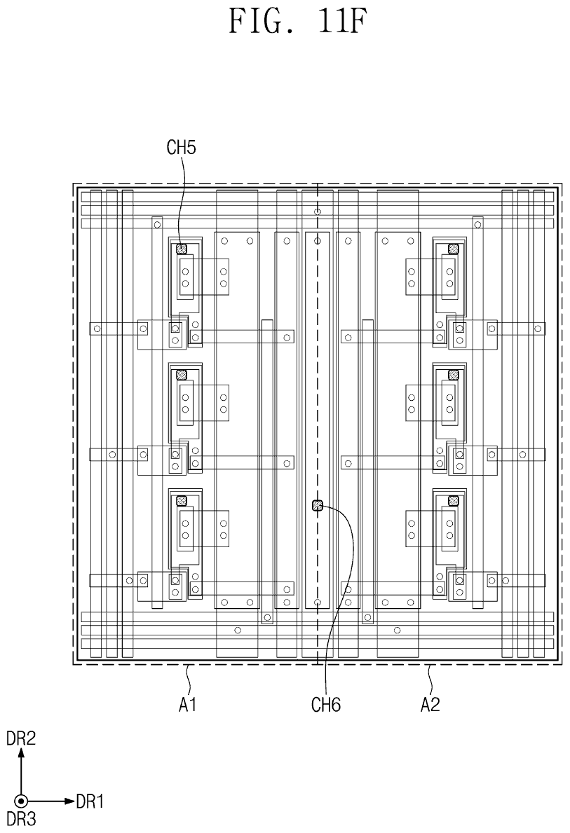

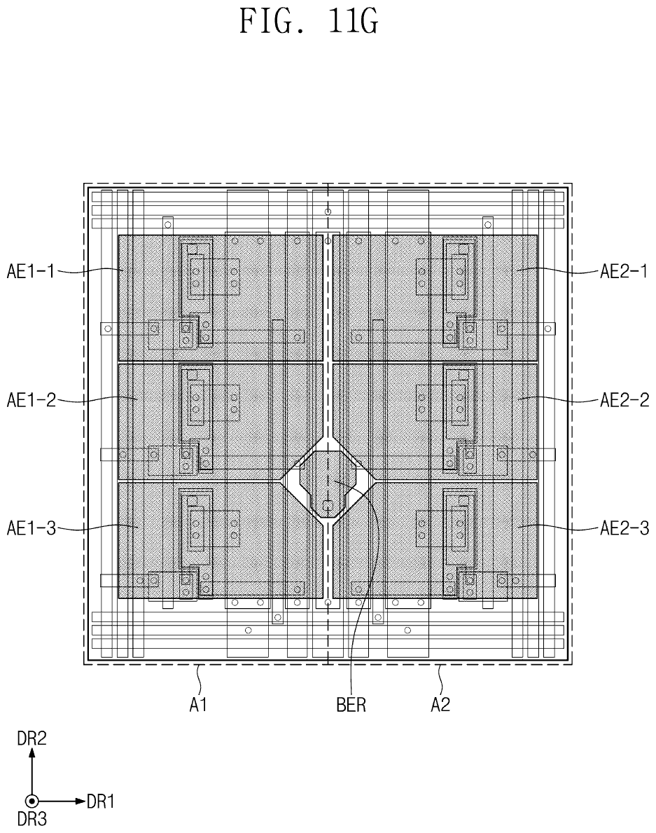

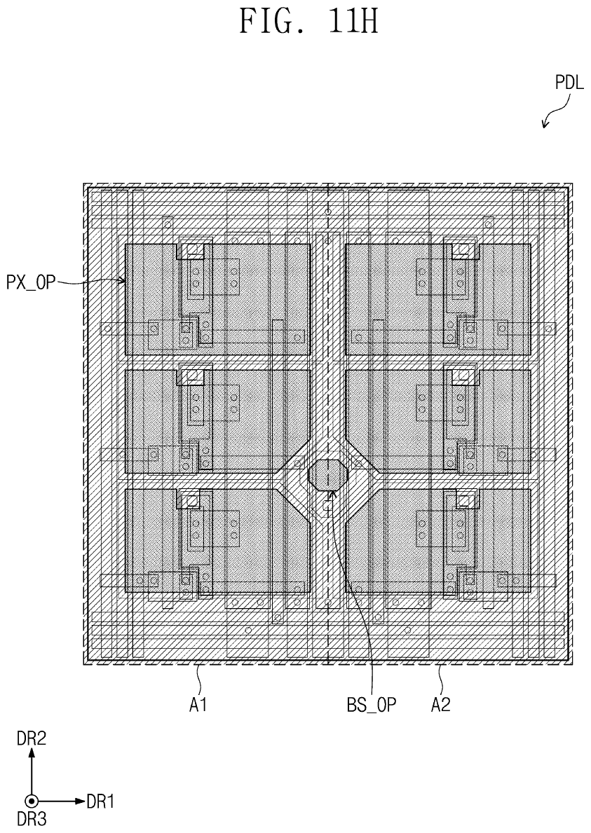

FIGS. 11A to 11H are plan views sequentially illustrating a planar structure of some of the pixels illustrated in FIG. 9.

FIGS. 11A to 11H may be defined as layout drawings of the pixel PX (see FIG. 9). Hereinafter, FIGS. 11A to 11H will illustrate a configuration of one display part LEP (see FIG. 9).

For convenience of description, among the regions separated by dotted lines illustrated in FIGS. 11A to 11H, a first region A1 may be defined as a region corresponding to the first portion PT1, and a second region A2 may be defined as a region corresponding to the second portion PT2.

For convenience of description, in FIGS. 11A to 11H, the description will be focused on the first pixel transistors T1, T2, and T3 and the first light-emitting elements OLED1 in the first portion PT1 of FIG. 9, but the second portion PT2 may also be substantially identical or similar to the first portion PT1 except for being symmetrical to the first portion PT1 with respect to the first direction DR1.

Among components illustrated in FIGS. 11A to 11H, the description of components which are described with reference to the above-described drawings and are identical or similar to the described components will be omitted or abbreviated.

Referring to FIG. 11A, a lower conductive pattern BMP may be disposed on a substrate SUB. A lower metal layer BML and data lines DL may be formed from the lower conductive pattern BMP. The data lines DL may be disposed adjacent to both sides of the substrate SUB, opposed to each other in the first direction DR1. The lower metal layer BML may be disposed between the data lines DL spaced apart from each other in the first direction DR1.

The data lines DL may extend in the second direction DR2. The data lines DL may include jth data lines DLj, (j+1)th data lines DLj+1, and (j+2)th data lines DLj+2. The jth data lines DLj, the (j+1)th data lines DLj+1, the (j+2)th data lines DLj+2 may be arranged in the first direction DR1. The jth data lines DLj may be disposed further outward than the (j+1)th data lines DLj+1. The (j+2)th data lines DLj+2 may be disposed further inward than the (j+1)th data lines DLj+1.

The lower metal layer BML may include first lower metal layers BML1 and second lower metal layers BML2. The first lower metal layers BML1 may extend in the second direction DR2, and be arranged in the first direction DR1. The first lower metal layers BML1 may include (1-1)-th lower metal layers BML1-1, (1-2)-th lower metal layers BML1-2, and (1-3)-th lower metal layer BML1-3.

The (1-2)-th lower metal layers BML1-2 may be disposed on both sides of the (1-3)-th lower metal layer BML1-3, opposed to each other in the first direction DR1. The (1-3)-th lower metal layer BML1-3 may be disposed between the (1-2)-th lower metal layers BML1-2. The (1-1)-th lower metal layers BML1-1 may be disposed adjacent to one sides spaced apart from the (1-3)-th lower metal layer BML1-3 among both sides of the (1-2)-th lower metal layers BML1-2, opposed to each other in the first direction DR1. The (1-2)-th lower metal layers BML1-2 and the (1-3)-th lower metal layer BML1-3 may be disposed between the (1-1)-th lower metal layers BML1-1.

The second lower metal layers BML2 may be disposed between the data lines DL and the first lower metal layers BML1. The second lower metal layers BML2 may be arranged in the second direction DR2.

Referring to FIGS. 11A and 11B, semiconductor patterns SMP may be disposed on the lower conductive pattern BMP. First to third source regions S1, S2, and S3, first to third drain regions D1, D2, and D3, and first to third channel regions A1, A2, and A3 of the first to third transistors T1, T2, and T3 (see FIG. 7) may be formed from the semiconductor patterns SMP. The first to third channel regions A1, A2, and A3 may be respectively disposed between the first to third source regions S1, S2, and S3, and the first to third drain regions D1, D2, and D3.

A portion of the first drain regions D1 may be disposed on the first lower metal layers BML1. A portion of the first source regions S1 may be disposed on the second lower metal layers BML2. A portion of the third drain regions D3 may be disposed on the first lower metal layers BML1. A portion of the third source regions S3 may be disposed on the second lower metal layers BML2.

Referring to FIGS. 11A to 11C, a gate pattern GPT may be disposed on the semiconductor patterns SMP. The gate pattern GPT may include a first gate pattern GPT1, a second gate pattern GPT2, and a third gate pattern GPT3.

The first gate pattern GPT1 may overlap the first channel region A1. The first gate electrode G1 may be formed from the first gate pattern GPT1. The second gate pattern GPT2 may overlap the second channel region A2. A second gate electrode G2 may be formed from the second gate pattern GPT2. The third gate pattern GPT3 may overlap the third channel region A3. A third gate electrode G3 may be formed from the third gate pattern GPT3.

Referring to FIGS. 7, 10, 11A to 11E, a connection pattern CNP of FIG. 11E may be disposed on the gate pattern GPT. The connection pattern CNP may include a plurality of first power lines PL1, a second power line PL2, a plurality of hth reference lines RLh, a plurality of first connection electrodes CNE1, a plurality of second connection electrodes CNE2, a plurality of third connection electrodes CNE3, sampling scan lines SSLi and SSLi-1, write scan lines SCLi and SCLi_1, and dummy lines DME.

The first power lines PL1 may be connected to the (1-1)-th lower metal layer BML1-1 via a plurality of first holes H1 overlapping the (1-1)-th lower metal layer BML1-1. The first power lines PL1 may be connected to the first transistors T1 via a plurality of second holes H2 overlapping the first drain regions D1. The first holes H1 may be substantially the first contact hole CH1 of FIG. 10. The second holes H2 may be substantially the second contact hole CH2 of FIG. 10.

The second power line PL2 may be disposed between the first power lines PL1. The second power line PL2 may be connected to the (1-3)-th lower metal layer BML1-3 via third holes H3 overlapping the (1-3)-th lower metal layer BML1-3 and spaced apart from each other in the second direction DR2. The third holes H3 may be substantially the fourth contact hole CH4 illustrated in FIG. 10.

The hth reference lines RLh may be disposed between the first power lines PL1 and the second power line PL2. When viewed on a plane, a first reference line RLh1 may be disposed on a left side of the second power line PL2, and a second reference line RLh2 may be disposed on a right side of the second power line PL2.

The reference lines RLh may be connected to the (1-2)-th lower metal layers BML1-2 via fourth holes H4 overlapping the (1-2)-th lower metal layers BML1-2 and spaced apart from each other in the second direction DR2. The reference lines RLh may be connected to the third transistors T3 via fifth holes H5 arranged in the second direction DR2 and overlapping the third drain regions D3 of the third transistors T3.

An ith write scan line SCLi may be disposed on one side among both sides of the second power line PL2, opposed to each other in the second direction DR2. An ith sampling scan line SSLi may be disposed on the other side among both sides of the second power line PL2, opposed to each other in the second direction DR2. The ith write scan line SCLi and the ith sampling scan line SSLi may extend in the first direction DR1.

The ith write scan line SCLi may overlap sixth holes H6 overlapping the second gate patterns GPT2. The ith write scan line SCLi may be connected to the second transistors T2 via the sixth holes H6. The ith write scan line SCLi may be connected to the second gate electrodes G2 of the second transistors T2.

The ith sampling scan line SSLi may overlap seventh holes H7 overlapping the third gate patterns GPT3. The ith sampling scan line SSLi may be connected to the third transistors T3 via the seventh holes H7. The ith sampling scan line SSLi may be connected to the third gate electrodes G3 of the third transistors T3.

Dummy lines DME may be disposed outside the ith write scan line SCLi and the ith sampling scan line SSLi. The dummy lines DME may be adjacent to both sides of the substrate SUB, opposed to each other in the second direction DR2 further than the ith write scan line SCLi and the ith sampling scan line SSLi.

The dummy line DML, among the dummy lines DML, adjacent to the ith write scan line SCLi may be connected to the (1-3)-th lower metal layer BML1-3 via an eighth hole H8 overlapping the (1-3)-th lower metal layer BML1-3. The dummy line DML, among the dummy lines DML, adjacent to the ith sampling scan line SSLi may be connected to the (1-1)-th lower metal layers BML1-1 via a ninth hole H9 overlapping the (1-1)-th lower metal layers BML1-1.

An (i−1)th sampling scan line SSLi-1 may be disposed on one side adjacent to the ith write scan line SCLi among both sides of the substrate SUB, opposed to each other in the second direction DR2. The (i−1)th sampling scan line SSLi-1 may be disposed further outward than the dummy line DML. The (i−1)th sampling scan line SSLi-1 may be connected to the third transistors T3 of a previous stage.

The (i+1)th write scan line SCLi+1 may be disposed on the other side among both sides of the substrate SUB, opposed to each other in the second direction DR2. An (i+1)th write scan line SCLi+1 may be disposed further outward than the dummy line DML. The (i+1)th write scan line SCLi+1 may be connected to the second transistors T2 of a next stage.

First connection electrodes CNE1 may overlap the first transistors T1. The first connection electrodes CNE1 may overlap tenth holes H10 overlapping the first source regions S1 and arranged in the second direction DR2. The first connection electrodes CNE1 may be connected to the first source regions S1 via the tenth holes H10. The first connection electrodes CNE1 may be substantially the connection electrode CNE of FIG. 10.

The first connection electrodes CNE1 may overlap eleventh holes H11 overlapping the second lower metal layers BML2. The first connection electrodes CNE1 may be connected to the second lower metal layers BML2 via the eleventh holes H11.

The first connection electrodes CNE1 may overlap twelfth holes H12 overlapping the third source regions S3 of the third transistors T3. The first connection electrodes CNE1 may be connected to the third source regions S3 via the twelfth holes H12. The first transistors T1 may be connected to the third transistors T3 via the first connection electrodes CNE1.

Second connection electrodes CNE2 may connect the second transistors T2 and the data lines DL via thirteenth holes H13 overlapping the data lines DL. Specifically, the second connection electrodes CNE2 may include a (2-1)-th connection electrode CNE2-1, a (2-2)-th connection electrode CNE2-2, and a (2-3)-th connection electrode CNE2-3.

The (2-1)-th connection electrode CNE2-1 may connect the second drain region D2 of the (1-1)-th pixel PX1-1 (see FIG. 9) and the jth data line DLj. The (2-1)-th connection electrode CNE2-1 may be connected to the second drain region D2 of the (1-1)-th pixel PX1-1 (see FIG. 9) via a fourteenth hole CN14 overlapping the second drain region D2 of the (1-1)-th pixel PX1-1 (see FIG. 9). The (2-1)-th connection electrode CNE2-1 may be connected to the jth data line DLj via a (13-1)-th hole H13-1 overlapping the jth data line DLj. Accordingly, the (2-1)-th connection electrode CNE2-1 may connect the (1-1)-th pixel PX1-1 illustrated in FIG. 9 and the jth data line DLj.

The (2-2)-th connection electrode CNE2-2 may connect the second drain region D2 of the (1-2)-th pixel PX1-2 (see FIG. 9) and the (j+1)th data line DLj+1. The (2-2)-th connection electrode CNE2-2 may be connected to the second drain region D2 of the (1-2)-th pixel PX1-2 (see FIG. 9) via the fourteenth hole CN14 overlapping the second drain region D2 of the (1-2)-th pixel PX1-2 (see FIG. 9). The (2-2)-th connection electrode CNE2-2 may be connected to the (j+1)th data line DLj+1 via a (13-2)-th hole H13-2 overlapping the (j+1)th data line DLj+1. Accordingly, the (2-2)-th connection electrode CNE2-2 may connect the (1-2)-th pixel PX1-2 illustrated in FIG. 9 and the (j+1)th data line DLj+1.

The (2-3)-th connection electrode CNE2-3 may connect the second drain region D2 of the (1-3)-th pixel PX1-3 (see FIG. 9) and the (j+2)th data line DLj+2. The (2-3)-th connection electrode CNE2-3 may be connected to the second drain region D2 of the (1-3)-th pixel PX1-3 (see FIG. 9) via the fourteenth hole CN14 overlapping the second drain region D2 of the (1-3)-th pixel PX1-3 (see FIG. 9). The (2-3)-th connection electrode CNE2-3 may be connected to the (j+2)th data line DLj+2 via a (13-3)-th hole H13-3 overlapping the (j+2)th data line DLj+2. Accordingly, the (2-3)-th connection electrode CNE2-3 may connect the (1-3)-th pixel PX1-3 illustrated in FIG. 9 and the (j+2)th data line DLj+2.

Third connection electrodes CNE3 may overlap the first gate patterns GPT1 and the second source regions S2 of the second transistors T2. The third connection electrodes CNE3 may be disposed on fifteenth holes H15 overlapping the first gate patterns GPT1. The third connection electrodes CNE3 may be connected to the first gate patterns GPT1 via the fifteenth holes H15.

The third connection electrodes CNE3 may be disposed on sixteenth holes H16 overlapping the second source regions S2 of the second transistors T2. The third connection electrodes CNE3 may be connected to the second source regions S2 via the sixteenth holes H16. The first gate patterns GPT1 and the second source regions S2 may be connected to each other via the third connection electrodes CNE3. The first transistors T1 and the second transistors T2 may be connected to each other via the third connection electrodes CNE3.

Referring to FIGS. 10 to 11F, fifth contact holes CH5 may be defined on the first transistors T1. Sixth contact holes CH6 may be defined on the second power line PL2.

Referring to FIGS. 10, 11F, and 11G, the first electrodes AE and the bus electrode BER may be disposed on the connection pattern CNP. The first electrodes AE may be arranged in the first direction DR1 and the second direction DR2. The first electrodes AE may include (1-1)-th to (1-3)-th electrodes AE1-1, AE1-2, and AE1-3, and (2-1)-th to (2-3)-th electrodes AE2-1, AE2-2, and AE2-3. The (1-1)-th to (1-3)-th electrodes AE1-1, AE1-2, and AE1-3 may be defined as the first electrodes AE disposed in the first portion PT1 of FIG. 9, and the (2-1)-th to (2-3)-th electrodes AE2-1, AE2-2, and AE2-3 may be defined as the first electrodes AE disposed in the second portion PT2 of FIG. 9.

The (1-1)-th electrode AE1-1 may be an anode of the (1-1)-th light-emitting element OLED1-1 of FIG. 9. The (1-2)-th electrode AE1-2 may be an anode of the (1-2)-th light-emitting element OLED1-2 of FIG. 9. The (1-3)-th electrode AE1-3 may be an anode of the (1-3)-th light-emitting element OELD1-3 of FIG. 9. The (2-1)-th electrode AE2-1 may be an anode of the (2-1)-th light-emitting element OELD2-1 of FIG. 9. The (2-2)-th electrode AE2-2 may be an anode of the (2-2)-th light-emitting element OELD2-2 of FIG. 9. The (2-3)-th electrode AE2-3 may be an anode of the (2-3)-th light-emitting element OLED2-3 of FIG. 9.

The first electrodes AE may each be connected to the corresponding first to third transistors T1, T2, and T3 among the first to third transistors T1, T2, and T3 via the fifth contact holes CH5.

The bus electrode BER may overlap a sixth contact hole CH6 overlapping the second power line PL2. The bus electrode BER may overlap the second power line PL2. The bus electrode BER may be connected to the second power line PL2 via the sixth contact hole CH6.

The bus electrode BER may be surrounded by the (1-2)-th electrode AE1-2, the (1-3)-th electrode AE1-3, the (2-2)-th electrode AE2-2, and the (2-3)-th electrode AE2-3. An edge of the (1-2)-th electrode AE1-2, an edge of the (1-3)-th electrode AE1-3, an edge of the (2-2)-th electrode AE2-2, and an edge of the (2-3)-th electrode AE2-3 which are adjacent to the bus electrode BER may have a shape corresponding to the bus electrode BER. For example, the edge of the (1-2)-th electrode AE1-2, the edge of the (1-3)-th electrode AE1-3, the edge of the (2-2)-th electrode AE2-2, and the edge of the (2-3)-th electrode AE2-3 may have inclination.

Referring to FIGS. 10 and 11A to 11H, the pixel-defining film PDL may be disposed on the first electrodes AE and the bus electrode BER. The pixel-defining film PDL may cover a border of the first electrodes AE. The first electrodes AE may be partially exposed by the pixel-defining film PDL to the outside through the pixel openings PX_OP defined by the pixel-defining film PDL.

Referring to FIGS. 9, 10, and 11H, thereafter, the light-emitting layers EML may be disposed on the first electrodes AE exposed by the pixel-defining film PDL to the outside. The light-emitting layers EML are disposed, and then the second electrode CE may be disposed on the light-emitting layers EML, a portion, of the bus electrode BER, exposed to the outside, and the pixel-defining film PDL in common. The second electrode CE may be in contact with the bus electrode BER via a contact opening BS_OP.

The second power line PL2 is provided in plurality, and one second power line PL2 among the second power lines PL2 may apply a second voltage to the first light-emitting elements OLED1, and the other second power line PL2 may apply a second voltage to the second light-emitting elements OLED2. In this case, as the number of second power lines PL2 is increased, an area of the display part LEP may be increased, and areas of the transmissive parts TAP may be decreased.

In some aspects, the bus electrode BER is provided in plurality, and the bus electrodes BER may be disposed so as to overlap the second power lines PL2. At this point, the second power lines PL2 and the bus electrodes BER may be disposed so as to be adjacent to both sides of the display part LEP, opposed to each other in the first direction DR1. The bus electrodes BER may have an asymmetrical shape, which may prevent interference with the transmissive parts TAP. In an example in which the pixel openings PX_OP have an asymmetric shape, areas of the pixel openings PX_OP may be decreased to prevent interference with the contact openings BS_OP.

However, according to an embodiment of the inventive concept, since the second power line PL2 is disposed between the first light-emitting elements OLED1 and the second light-emitting elements OLED2, the second voltage may be applied to the first light-emitting elements OLED1 and the second light-emitting elements OLED2 in common. Accordingly, the number of second power lines PL2 is reduced, and the area of the display part LEP may be decreased. Therefore, the areas of the transmissive parts TAP may be increased.

In some aspects, when viewed on a plane, since the bus electrode BER has the shape symmetrical with respect to the first direction DR1, areas of the pixel openings PX_OP subjected to a decrease may be minimized. Therefore, the areas of the light-emitting regions PA may be increased.

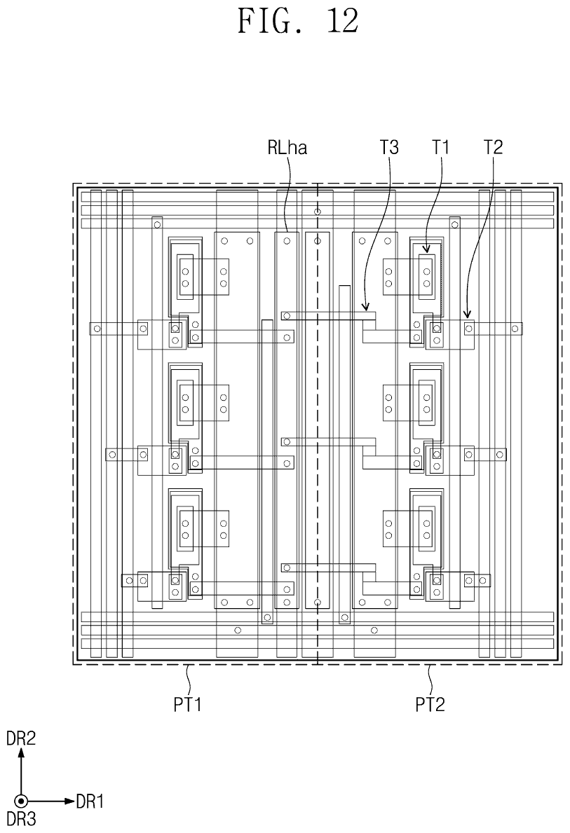

FIG. 12 is a plan view of a light-emitting part according to an embodiment of the inventive concept.

For convenience of description, the connection patterns CNP (see FIG. 11E), the first electrode AE (see FIG. 11G), the bus electrode BER (see FIG. 11G), and the pixel-defining film PDL (see FIG. 11H) are omitted.

Among components illustrated in FIG. 12, the description of components which are described with reference to the above-described drawings and are identical or similar to the described components will be omitted or abbreviated.

Referring to FIG. 12, transistors T1, T2, and T3 disposed in a first portion PT1 may be defined as first pixel transistors T1, T2, and T3. The transistors T1, T2, and T3 disposed in a second portion PT2 may be defined as second pixel transistors T1, T2, and T3.

The third transistors T3 disposed in the second portion PT2 may extend toward the first portion PT1 in the first direction DR1. A hth reference line RLha may be connected to the transistors T1, T2, and T3 via the fifth hole H5. Specifically, the hth reference line RLha may be connected to the first pixel transistors T1, T2, and T3 via a (5-1)-th hole H5-1. The hth reference line RLha may be connected to the second pixel transistors T1, T2, and T3 via a (5-2)-th hole H5-2. The reference line RLha may apply a reference voltage to the first pixel transistors T1, T2, and T3. The reference line RLha may apply a reference voltage to the second pixel transistors T1, T2, and T3.

As the hth reference line RLha applies the reference voltage to the first pixel transistors T1, T2, and T3 and the second pixel transistors T1, T2, and T3 in common, an area of the display part LEP may be decreased compared to when the hth reference line RLha is provided in plurality. Therefore, areas of the transmissive parts TAP may be increased.

According to an embodiment of the inventive concept, a second power line connected to first light-emitting elements may be connected to second light-emitting elements. Accordingly, the number of second power lines may be reduced, and thus areas of transmissive parts may be increased.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. An electronic device comprising:
a substrate comprising a light-emitting part and a plurality of transmissive parts adjacent to the light-emitting part; and
a pixel unit disposed on the light-emitting part,
wherein the pixel unit comprises:
a first portion comprising a plurality of first light-emitting elements which are arranged in a first direction,
a second portion symmetrical with the first portion with respect to an axis parallel to the first direction and comprising a plurality of second light-emitting elements which are arranged in the first direction,
a bus electrode disposed between the first portion and the second portion when viewed on a plane, and
a pixel-defining film covering a border of the bus electrode and exposing a portion of the bus electrode.

2. The electronic device of claim 1, wherein the first portion further comprises:
a plurality of first pixel transistors disposed below the plurality of first light-emitting elements and electrically connected to the plurality of first light-emitting elements;
a (1-1)-th power line disposed between the plurality of first light-emitting elements and the plurality of first pixel transistors, electrically connected to the plurality of first light-emitting elements, and which applies a first voltage to the plurality of first light-emitting elements; and
a second power line disposed between the plurality of first light-emitting elements and the plurality of first pixel transistors, electrically connected to the plurality of first light-emitting elements, and which applies a second voltage having a lower level than the first voltage to the plurality of first light-emitting elements.

3. The electronic device of claim 2, wherein:
the second portion further comprises:
second pixel transistors disposed below the plurality of second light-emitting elements and electrically connected to the plurality of second light-emitting elements; and
a (1-2)-th power line disposed between the plurality of second light-emitting elements and the second pixel transistors, electrically connected to the plurality of second light-emitting elements, and which applies the first voltage to the plurality of second light-emitting elements, and
the second power line is electrically connected to the plurality of second light-emitting elements and applies the second voltage.

4. The electronic device of claim 3, wherein when viewed on a plane, the second power line is disposed between the plurality of first pixel transistors and the second pixel transistors.

5. The electronic device of claim 3, wherein:
when viewed on a plane, the second power line overlaps the bus electrode, and
the bus electrode and the second power line are electrically connected to each other.

6. The electronic device of claim 5, wherein:
the plurality of first light-emitting elements each comprise:
a first electrode connected to the plurality of first pixel transistors and at least partially exposed by the pixel-defining film;
a second electrode disposed on the first electrode; and
a light-emitting layer disposed between the first electrode and the second electrode, and
the second electrode is in contact with the bus electrode which is exposed by the pixel-defining film to the outside.

7. The electronic device of claim 3, wherein the first portion further comprises a first reference line disposed between the plurality of first pixel transistors and the plurality of first light-emitting elements, electrically connected to the plurality of first pixel transistors, and which applies a reference voltage to the plurality of first pixel transistors.

8. The electronic device of claim 7, wherein the first reference line applies the reference voltage to the second pixel transistors.

9. The electronic device of claim 7, wherein the second portion further comprises a second reference line disposed between the second pixel transistors and the plurality of second light-emitting elements, electrically connected to the second pixel transistors, and which applies a reference voltage to the second pixel transistors.

10. The electronic device of claim 1, wherein when viewed on a plane, the bus electrode is laterally symmetrical with respect to a symmetry axis parallel to the first direction.

11. The electronic device of claim 1, wherein:
the plurality of first light-emitting elements comprise a (1-1)-th light-emitting element, a (1-2)-th light-emitting element, and a (1-3)-th light-emitting element which respectively emit light of different colors, and
the plurality of second light-emitting elements comprise a (2-1)-th light-emitting element, a (2-2)-th light-emitting element, and a (2-3)-th light-emitting element which respectively emit light of different colors.

12. The electronic device of claim 11, wherein:
when viewed on a plane, the bus electrode is surrounded by the (1-2)-th light-emitting element, the (1-3)-th light-emitting element, the (2-2)-th light-emitting element, and the (2-3)-th light-emitting element, and
an edge of the (1-2)-th light-emitting element, an edge of the (1-3)-th light-emitting element, an edge of the (2-2)-th light-emitting element, and an edge of the (2-3)-th light-emitting element, which are adjacent to the bus electrode, have a shape corresponding to a shape of the bus electrode.

13. An electronic device comprising:
a substrate comprising a light-emitting part and a plurality of transmissive parts adjacent to the light-emitting part; and
a pixel unit disposed on the light-emitting part,
wherein the pixel unit comprises:
a first portion comprising a plurality of first pixel transistors which are disposed on the substrate and a plurality of first light-emitting elements which are disposed on the plurality of first pixel transistors and electrically connected to the plurality of first pixel transistors,
a second portion comprising a plurality of second pixel transistors which are disposed on the substrate and a plurality of second light-emitting elements which are disposed on the plurality of second pixel transistors and electrically connected to the plurality of second pixel transistors,
a (1-1)-th power line disposed between the plurality of first pixel transistors and the plurality of first light-emitting elements, electrically connected to the plurality of first light-emitting elements, and which applies a first voltage,
a (1-2)-th power line disposed between the plurality of second pixel transistors and the plurality of second light-emitting elements, electrically connected to the plurality of second light-emitting elements, and which applies the first voltage, and
a second power line disposed between the first portion and the second portion when viewed on a plane, electrically connected to the plurality of first light-emitting elements and the plurality of second light-emitting elements, and which applies a second voltage having a lower level than the first voltage.

14. The electronic device of claim 13, wherein the plurality of first light-emitting elements each comprise:
a first electrode connected to the plurality of first pixel transistors;
a second electrode disposed on the first electrode; and
a light-emitting layer disposed between the first electrode and the second electrode.

15. The electronic device of claim 14, wherein:
the pixel unit comprises a bus electrode disposed between the first portion and the second portion and disposed at the same plane as the first electrode, and
the second electrode is in contact with the bus electrode.

16. The electronic device of claim 15, wherein:
the bus electrode overlaps the second power line when viewed on a plane, and
the bus electrode and the second power line are electrically connected to each other.

17. The electronic device of claim 13, wherein the pixel unit further comprises a first reference line disposed between the plurality of first pixel transistors and the plurality of first light-emitting elements, electrically connected to the plurality of first pixel transistors, and which applies a reference voltage to the plurality of first pixel transistors.

18. The electronic device of claim 17, wherein the first reference line applies the reference voltage to the plurality of second pixel transistors.

19. The electronic device of claim 17, wherein the pixel unit further comprises a second reference line disposed between the plurality of second pixel transistors and the plurality of second light-emitting elements, electrically connected to the plurality of second pixel transistors, and which applies a reference voltage to the plurality of second pixel transistors.

20. An electronic device comprising:
a power module; and
a display module electrically connected to the power module,
wherein:
the display module comprises:
a substrate comprising a light-emitting part and a plurality of transmissive parts which are adjacent to the light-emitting part, and
a pixel unit disposed on the light-emitting part, and
the pixel unit comprises:
a first portion comprising a plurality of first light-emitting elements which are arranged in a first direction,
a second portion symmetrical with the first portion with respect to an axis parallel to the first direction, and comprising a plurality of second light-emitting elements which are arranged in the first direction,
a bus electrode disposed between the first portion and the second portion when viewed on a plane, and
a pixel-defining film covering a border of the bus electrode and exposing a portion of the bus electrode.
